(19) United States
(12) Patent Application Publication
(10) Pub. No.: US 2013/0155603 A1
(43) Pub. Date: Jun. 20, 2013

(54) SUPPLEMENTARY DISK-ENCLOSURE COVER CONFIGURED TO SHIELD A HARD-DISK DRIVE AGAINST ELECTROMAGNETIC INTERFERENCE

(71) Applicants: Jiro Kaneko, Kanagawa (JP); Takeshi Chawanya, Kanagawa (JP); Masahiko Tamura, Kanagawa (JP); Keiichiroh Kai, Kanagawa (JP)

(72) Inventors: Jiro Kaneko, Kanagawa (JP); Takeshi Chawanya, Kanagawa (JP); Masahiko Tamura, Kanagawa (JP); Keiichiroh Kai, Kanagawa (JP)

(21) Appl. No.: 13/326,319

(22) Filed: Dec. 15, 2011

(51) Int. Cl. H05K 9/00; G06F 1/16

(52) U.S. Cl. 361/679.33; 174/377

(57) ABSTRACT

A supplementary disk-enclosure cover configured to shield a hard-disk drive against electromagnetic interference. The supplementary disk-enclosure cover includes a top, and vertical flanges. The top has an outer perimeter and an inner perimeter. The outer perimeter lies about parallel to the inner perimeter. The top is disposed between the outer perimeter and the inner perimeter and has a flattened annular shape. The vertical flanges are attached to and extend down from the outer perimeter of the top at about right angles to the top. The vertical flanges are configured to cover respective gaps between a disk-enclosure cover and a disk-enclosure base to which the disk-enclosure cover is attached. A disk enclosure that includes the supplementary disk-enclosure cover, and a hard-disk drive that includes the disk enclosure are also provided.

### TECHNICAL FIELD

Embodiments of the present invention relate generally to hard-disk drives (HDDs), and in particular to disk enclosures of HDDs.

### BACKGROUND

With the advance of HDD technology, the magnetic fields read by a magnetic-recording head from the recording surface of a magnetic-recording disk have become progressively smaller. Consequently, stray electromagnetic fields of low intensity have become of greater concern. For example, stray electromagnetic fields, as low as 7 volts/meter (V/m), can interfere with the read operation of the magnetic-recording head, and give rise to errors in the retrieval of information stored on the magnetic-recording disk. Thus, engineers and scientists engaged in the development of HDDs are interested in providing an HDD environment of high reliability for the retrieval of information, and HDD designs that can achieve such high reliability without excessive cost.

### SUMMARY

Embodiments of the present invention include a supplementary disk-enclosure cover configured to shield a hard-disk drive (HDD) against electromagnetic interference (EMI). The supplementary disk-enclosure cover includes a top, and vertical flanges. The top has an outer perimeter and an inner perimeter. The outer perimeter lies about parallel to the inner perimeter. The top is disposed between the outer perimeter and the inner perimeter and has a flattened annular shape. The vertical flanges are attached to and extend down from the outer perimeter of the top at about right angles to the top. The vertical flanges are configured to cover respective gaps between a disk-enclosure cover and a disk-enclosure base to which the disk-enclosure cover is attached. Other embodiments of the present invention include a disk enclosure that includes the supplementary disk-enclosure cover and is configured to shield a HDD against EMI, and the HDD that includes the disk enclosure and is shielded against EMI.

### DESCRIPTION OF THE DRAWINGS

The accompanying drawings, which are incorporated in and form a part of this specification, illustrate embodiments of the invention and, together with the description, serve to explain the embodiments of the invention:

FIG. 1 is a perspective view of a disk enclosure for a hard-disk drive (HDD), configured to shield the HDD against electromagnetic interference (EMI), in accordance with one or more embodiments of the present invention.

FIG. 2A is a perspective view of a supplementary disk-enclosure cover of the disk enclosure of FIG. 1 that is configured to shield a HDD against EMI, in accordance with one or more embodiments of the present invention.

FIG. 2B is a cross-sectional view of a cross-section at line 2B-2B of FIG. 2A detailing the structure of a vertical flange of the supplementary disk-enclosure cover of FIG. 2A that includes an inward projecting portion configured to press against a side of the disk-enclosure base of the disk enclosure of FIG. 1, in accordance with one or more one embodiments of the present invention.

FIG. 3 is a perspective view of the disk-enclosure base of the disk enclosure of FIG. 1, in accordance with one or more another embodiments of the present invention.

FIG. 4 is an exploded perspective view of the disk enclosure of FIG. 1 showing both the supplementary disk-enclosure cover and the disk-enclosure base, and detailing the configuration of the supplementary disk-enclosure cover and the disk-enclosure base that serves to shield a HDD against EMI, in accordance with one or more another embodiments of the present invention.

FIG. 5 is a perspective view of a HDD with the disk-enclosure cover of the disk enclosure of FIG. 1 removed, in accordance with one or more embodiments of the present invention.

The drawings referred to in this description should not be understood as being drawn to scale except if specifically noted.

### DESCRIPTION OF EMBODIMENTS

Reference will now be made in detail to the alternative embodiments of the present invention. While the invention will be described in conjunction with the alternative embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following description of embodiments of the present invention, numerous specific details are set forth in order to provide a thorough understanding of the present invention. However, it should be appreciated that embodiments of the present invention may be practiced without these specific details. In other instances, well known methods, procedures, and components have not been described in detail as not to unnecessarily obscure embodiments of the present invention. Throughout the drawings, like components are denoted by like reference numerals, and repetitive descriptions are omitted for clarity of explanation if not necessary.

### Physical Description of Embodiments of a Supplementary Disk-Enclosure Cover Configured to Shield a Hard-disk Drive (HDD) Against Electromagnetic Interference (EMI)

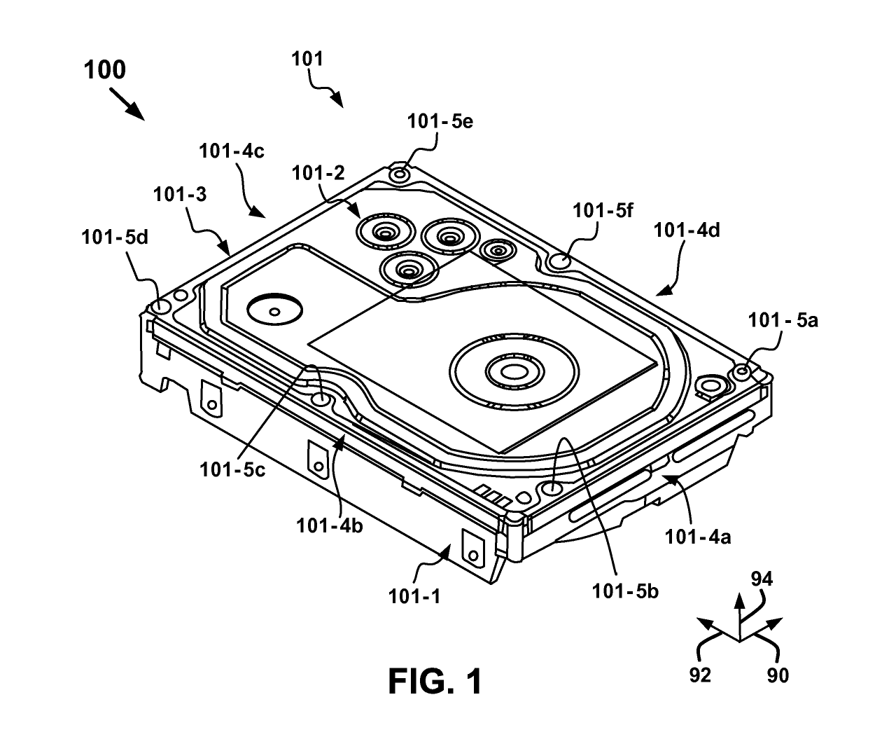

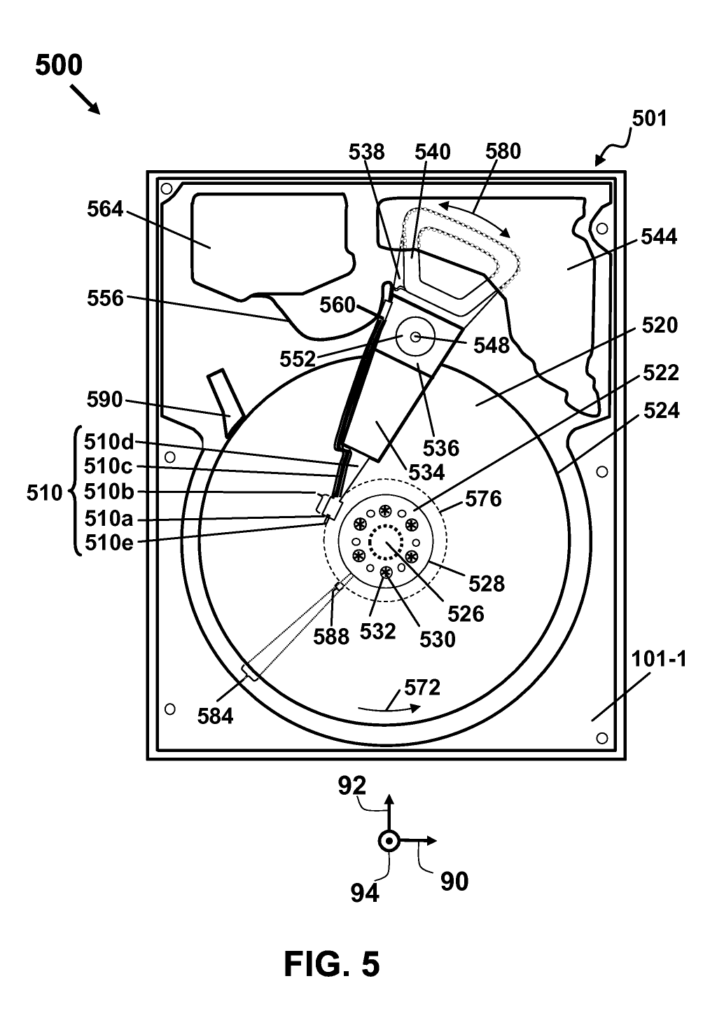

With reference now to FIG. 1, in accordance with one or more embodiments of the present invention, a perspective view 100 is shown of a disk enclosure 101 for a hard-disk drive (HDD) 501 (see FIG. 5). The disk enclosure 101 is configured to shield HDD 501 against electromagnetic interference (EMI). The disk enclosure 101 includes a disk-enclosure base 101-1, a disk-enclosure cover 101-2, and a supplementary disk-enclosure cover 101-3. The disk enclosure 101 includes a plurality of fasteners 101-5a, 101-5b, 101-5c, 101-5d, 101-5e and 101-5f. The fasteners 101-5a through 101-5f serve to fasten the disk-enclosure cover 101-2 to the disk-enclosure base 101-1 using the supplementary disk-enclosure cover 101-3 to clamp the disk-enclosure cover 101-2 to the disk-enclosure base 101-1. In one embodiment of the present invention, the fasteners 101-5a through 101-5f may be screws. These screws also provide electrical contacts between the supplementary disk-enclosure cover 101-3, the disk-enclosure cover 101-2, and the disk-enclosure base 101-1 at the location of the screws. Between the disk-enclosure cover 101-2 and the disk-enclosure base 101-1, an elastic O-ring (not shown) may be placed to seal the disk enclosure 101. As a result, along each side of the disk enclosure 101, there exists a gap between the disk-enclosure cover 101-2 and the disk-enclosure base 101-1, for example, gaps 101-4a, 101-4b, 101-4c and 101-4d. As shown in FIG. 1, in accordance with embodiments of the present invention, the gaps 101-4a, 101-4b, 101-4c and 101-4d are covered by the supplementary disk-enclosure cover 101-3.

In the absence of means for providing electrical coupling between the disk-enclosure cover 101-2 and the disk-enclosure base 101-1 within the region spanned by a gap, the gap provides a pathway for the admission of electromagnetic radiation, for example, radio waves. Thus, a disk enclosure without means for electrically coupling a disk-enclosure cover and a disk-enclosure base at the location of a gap acts as a leaky Faraday cage for admission of EMI, for example, radio frequency interference (RFI). When the level of the fields associated with this electromagnetic radiation exceeds a level of about 7 volts per meter (V/m) inside the disk enclosure 101 of HDD 501, the read operation of a magnetic-recording head that reads data from a magnetic-recording disk may be interfered with causing errors in the read-back signal from the magnetic-recording head, which gives rise to an increase in soft-error rate (SER). Embodiments of the present invention provide a means, namely, the supplementary disk-enclosure cover 101-3, to shield an interior space enclosed by the disk-enclosure base, for example, the disk-enclosure base 101-1, and the disk-enclosure cover, for example, the disk-enclosure cover 101-2, against EMI that may penetrate a disk enclosure at a gap. In accordance embodiments of the present invention, the supplementary disk-enclosure cover 101-3 may be readily incorporated into the fabrication process for the HDD without costly engineering changes to any of the other existing components of the disk enclosure. Thus, in accordance embodiments of the present invention, the supplementary disk-enclosure cover 101-3 provides a low cost means to increase the reliability of the HDD with respect to the effects of EMI by reducing SER.

With further reference to FIG. 1, in accordance with one or more embodiments of the present invention, a triad of arrows 90, 92 and 94 is used to indicate the relative orientation of components in disk enclosure 101; the direction of arrow 92 is about parallel to the long side of the disk-enclosure base 101-1 of disk enclosure 101; the direction of arrow 90 is perpendicular to arrow 92 and is about parallel to the short side of the disk-enclosure base 101-1 of disk enclosure 101; and, arrow 94 is about perpendicular to the plane of the disk-enclosure base 101-1, as well as the plane of the recording surface of the magnetic-recording disk 520 (see FIG. 5), and therefore is perpendicular to arrows 90 and 92. Thus, the triad of arrows 90, 92 and 94 are related to one another by the right-hand rule for vectors in the direction of the arrows 90, 92 and 94 such that the cross product of the vector corresponding to arrow 90 and the vector corresponding to arrow 92 produces a vector parallel and oriented in the direction of the arrow 94. The triad of arrows 90, 92 and 94 is subsequently used to indicate the orientation of views for subsequently described drawings of the disk enclosure 101. The terms of art, “top,” and “bottom,” refer to components the principal surfaces of which are disposed about normal to the arrow 94. The term of art, “vertical,” refers to a side, or a flange, that lies about parallel to the arrow 94. The term of art, “lateral,” refers to a side that is about normal to either of the arrows 90 and 92; and, the term of art, “laterally disposed,” refers to a component that is disposed on a side, or a flange, that lies about normal to either of the arrows 90 and 92. The term of art, “front,” refers to a side that is about normal to the arrow 92 at the right side of FIG. 1; for example, arrow 92 points to the front side of HDD 501 (see FIG. 5).

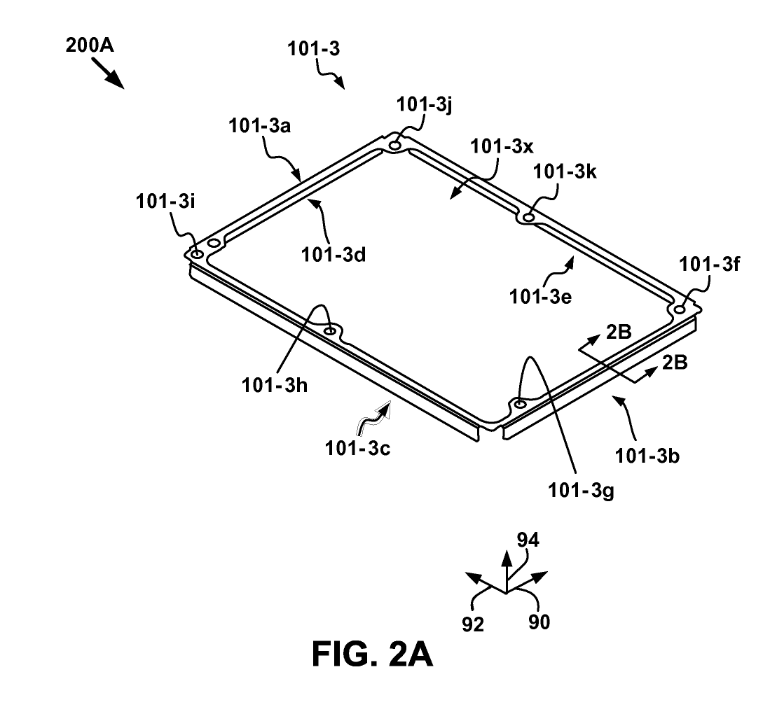

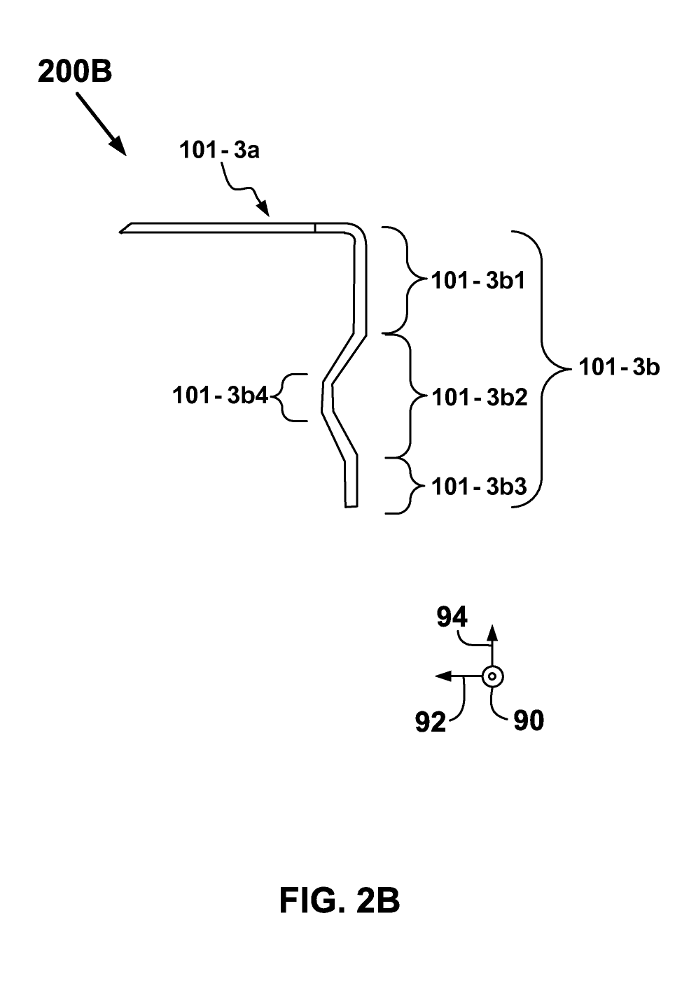

With reference now to FIG. 2A, in accordance with one or more embodiments of the present invention, a perspective view 200A is shown of the supplementary disk-enclosure cover 101-3 of the disk enclosure 101 of FIG. 1. The triad of arrows 90, 92 and 94 indicates the orientation of the perspective view 200A shown in FIG. 2A relative to the perspective view 100 shown in FIG. 1. The supplementary disk-enclosure cover 101-3 is configured to shield HDD 501 (see FIG. 5) against EMI. The supplementary disk-enclosure cover 101-3 includes a top 101-3a, and vertical flanges 101-3b, 101-3c, 101-3d and 101-3e. The top 101-3a has an outer perimeter and an inner perimeter. The outer perimeter lies about parallel to the inner perimeter. The outer perimeter may have about a rectangular shape, without limitation thereto. The top 101-3a is disposed between the outer perimeter and the inner perimeter and has a flattened annular shape. Thus, within the interior of the inner perimeter, there is a hole 101-3x in the supplementary disk-enclosure cover 101-3. The vertical flanges 101-3b through 101-3e are attached to and extend down from the outer perimeter of the top 101-3a at about right angles to the top 101-3a. The vertical flanges 101-3b, 101-3c, 101-3d and 101-3e are configured to cover gaps, for example, gaps 101-4a, 101-4b, 101-4c and 101-4d, respectively, between the disk-enclosure cover 101-2 and the disk-enclosure base 101-1 to which the disk-enclosure cover 101-2 is attached.

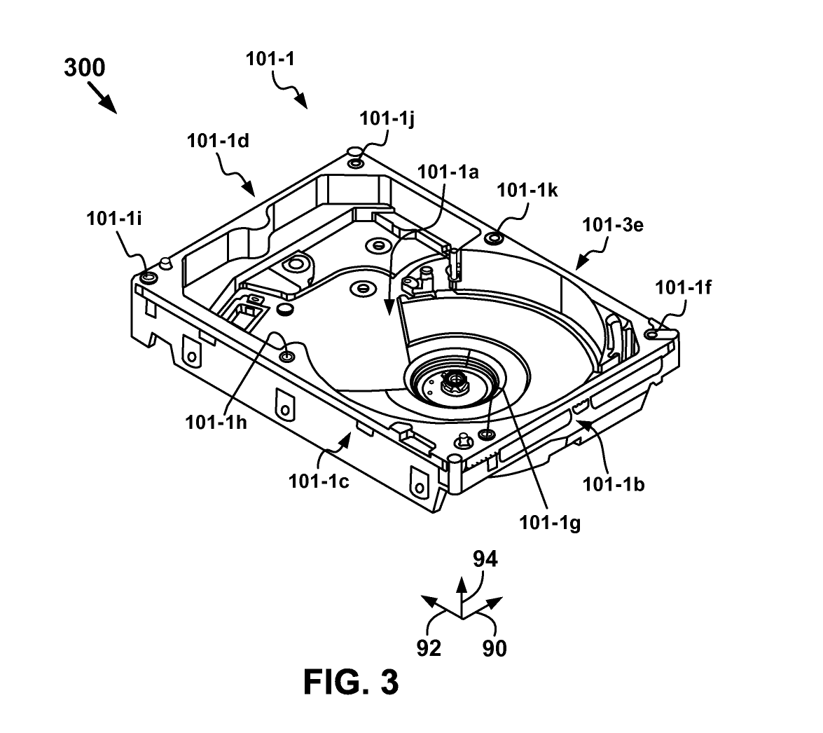

With further reference to FIGS. 2A and 1, in accordance with one or more embodiments of the present invention, the top 101-3a includes a plurality of supplementary holes 101-3f, 101-3g, 101-3h, 101-3i, 101-3j and 101-3k configured to accept fasteners 101-5a, 101-5b, 101-5c, 101-5d, 101-5e and 101-5f, respectively, to fasten the top 101-3a to the disk-enclosure base 101-1. The plurality of supplementary holes 101-3f, 101-3g, 101-3h, 101-3i, 101-3j and 101-3k is configured to align with a plurality of holes 101-1f, 101-1g, 101-1h, 101-1i, 101-1j and 101-1k (see FIG. 3), respectively, in the disk-enclosure base 101-1. The plurality of supplementary holes 101-3f through 101-3k is configured to align with a plurality of holes (not shown) in the disk-enclosure cover 101-2. The top 101-3a of the supplementary disk-enclosure cover 101-3 is configured to clamp the disk-enclosure cover 101-2 to the disk-enclosure base 101-1. As shown in FIG. 2, line 2B-2B denotes the location of the trace of a cross-sectioning plane for a cross-sectional view through the supplementary disk-enclosure cover 101-3 for describing the structure of the vertical flange 101-3b, which is next described in greater detail with the aid of FIG. 2B.

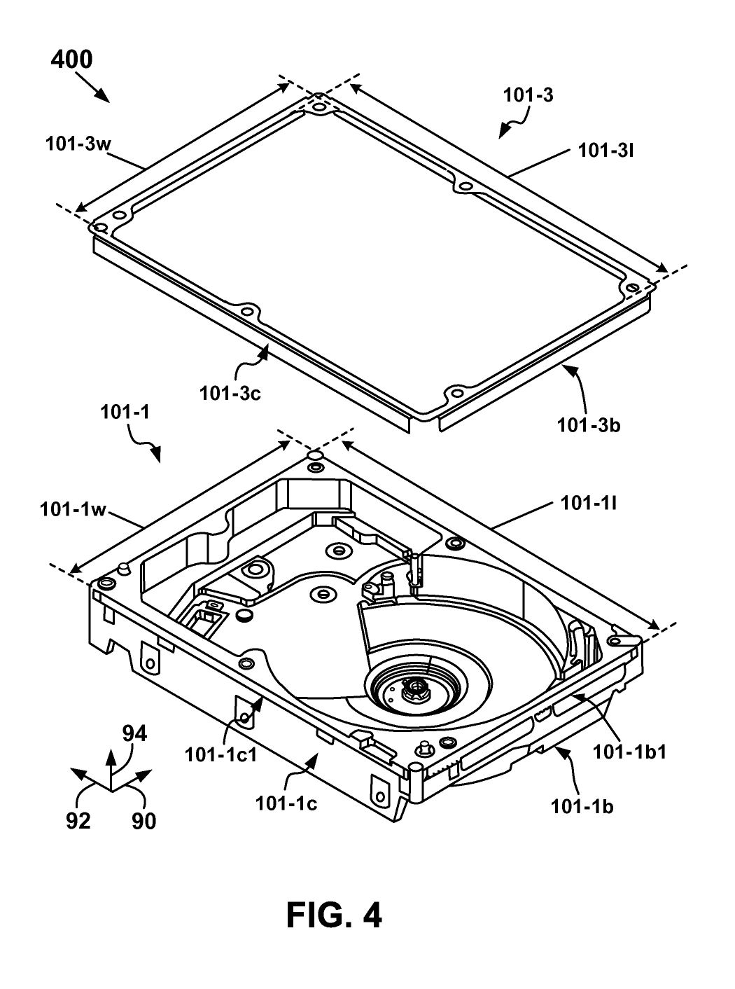

With reference now to FIG. 2B, in accordance with one or more embodiments of the present invention, a cross-sectional view 200B of the supplementary disk-enclosure cover 101-3 is shown of a cross-section at line 2B-2B of FIG. 2A. FIG. 2B illustrates the structure of the vertical flange 101-3b of the supplementary disk-enclosure cover 101-3 of FIG. 2A, which includes an inward projecting portion 101-3b2 configured to press against a side 101-1b of the disk-enclosure base 101-1 of the disk enclosure 101 of FIG. 1. The triad of arrows 90, 92 and 94 indicates the orientation of the cross-sectional view 200B shown in FIG. 2B relative to the perspective views 100 and 200A shown in FIGS. 1 and 2A, respectively. In accordance with embodiments of the present invention, the vertical flanges 101-3b through 101-3e, of which vertical flange 101-3b is an example, are configured to make electrical contact with the disk-enclosure base 101-1. In accordance with embodiments of the present invention, the supplementary disk-enclosure cover 101-3 is fabricated from a material with good electrical conductivity, such as a metal, for example, stainless steel, without limitation thereto. The vertical flange 101-3b includes a small vertical flange portion 101-3b1, an inward projecting portion 101-3b2, and a skirt 101-3b3. The inward projecting portion 101-3b2 is configured to press against a side 101-1b (see FIG. 3) of the disk-enclosure base 101-1. To facilitate contact with the side 101-1b (see FIG. 3) of the disk-enclosure base 101-1, the supplementary disk-enclosure cover 101-3 is fabricated from a material with good elasticity, such as spring steel. Certain grades of stainless steel may be heat treated to provide such a spring steel. The inward projecting portion 101-3b2 includes a contacting portion 101-3b4 that is configured to make electrical contact with the side 101-1b (see FIGS. 3 and 4) of the disk-enclosure base 101-1. The skirt 101-3b3 extends below the inward projecting portion 101-3b2, and is configured to be disposed about parallel to the side 101-1b (see FIG. 3) of the disk-enclosure base 101-1.

With reference now to FIG. 3, in accordance with one or more embodiments of the present invention, a perspective view 300 is shown of the disk-enclosure base 101-1 of the disk enclosure 101 of FIG. 1. The triad of arrows 90, 92 and 94 indicates the orientation of the perspective view 300 shown in FIG. 3 relative to the perspective view 100 shown in FIG. 1. The disk-enclosure base 101-1 includes a bottom 101-1a, and sides 101-1b, 101-1c, 101-1d and 101-1e. The sides 101-1b through 101-1e are attached to the bottom 101-1a in a boxlike configuration. The disk-enclosure base 101-1 also includes a plurality of holes 101-1f, 101-1g, 101-1h, 101-1i, 101-1j and 101-1k. The plurality of holes 101-1f, 101-1g, 101-1h, 101-1i, 101-1j and 101-1k are configured to accept the fasteners 101-5a, 101-5b, 101-5c, 101-5d, 101-5e and 101-5f, respectively, to fasten the top 101-3a of the supplementary disk-enclosure cover 101-3 (see FIGS. 1 and 2A) to the disk-enclosure base 101-1 with and the disk-enclosure cover 101-2 interposed therebetween.

With reference now to FIG. 4 and further reference to FIGS. 1-3, in accordance with one or more embodiments of the present invention, an exploded perspective view 400 is shown of the disk enclosure 101 of FIG. 1 including the disk-enclosure base 101-1 and the supplementary disk-enclosure cover 101-3. FIG. 4 shows the configuration of the supplementary disk-enclosure cover 101-3 and the disk-enclosure base 101 without the interposed disk-enclosure cover 101-2 to facilitate visualization of this configuration. Details are shown of the configuration of the supplementary disk-enclosure cover 101-3 and the disk-enclosure base 101 that serve to shield HDD 501 (see FIG. 5) against EMI. The triad of arrows 90, 92 and 94 indicates the orientation of the exploded perspective view 400 shown in FIG. 4 relative to the perspective view 100 shown in FIG. 1. In accordance with one embodiment of the present invention, a width 101-3w and a length 101-3l of the top 101-3a at the inner perimeter are less than a width 101-1w and a length 101-1l of the disk-enclosure base 101-1, without limitation thereto. In accordance with embodiments of the present invention, an e-coat layer is removed from the disk-enclosure base 101-1 at top portions of the sides 101-1b through 101-1e, for example, top portion 101-1b1 of the side 101-b, of the disk-enclosure base 101-1. The vertical flanges 101-3b through 101-3e include inward projecting portions, of which inward projecting portion 101-3b2 is an example, that press against the top portions of the sides 101-1b through 101-1e, of which top portions 101-1b1 and 101-1c1 of respective sides 101-1b and 101-1c are examples, of the disk-enclosure base 101-1. The vertical flange 101-3b and the supplementary disk-enclosure cover 101-3 are configured to shield an interior space enclosed by the disk-enclosure base 101-1 and the disk-enclosure cover 101-2 against EMI. To provide such shielding, for example, the supplementary disk-enclosure cover 101-3 is ohmically coupled with low impedance by the vertical flange 101-3b through the top portion 101-1b1 of the side 101-1b to the disk-enclosure base 101-1. Thus, in accordance with embodiments of the present invention, the supplementary disk-enclosure cover 101-3 shields an interior space enclosed by the disk-enclosure base 101-1 and the disk-enclosure cover 101-2 against EMI with a frequency of between about 200 MHz to about 2 GHz by reducing an electric field component of an electromagnetic field associated with the EMI within the interior space of the disk enclosure 101 to less than about 7 volts/meter (V/m).

With reference now to FIG. 5, in accordance with one or more embodiments of the present invention, a plan view 500 is shown of HDD 501 with the disk-enclosure cover 101-2 of the disk enclosure 101 of FIG. 1 removed. The triad of arrows 90, 92 and 94 indicates the orientation of the plan view 500 shown in FIG. 5 relative to the perspective view 100 shown in FIG. 1. FIG. 5 illustrates the arrangement of components of HDD 501 including the disk enclosure 101. In the subsequent description of HDD 501 and disk enclosure 101, embodiments of the present invention incorporate within the environment of HDD 501, without limitation, the previously described embodiments of the present invention for the disk enclosure 101 and for the supplementary disk-enclosure cover 101-3.

With further reference to FIG. 5, in accordance with one or more embodiments of the present invention, HDD 501 includes at least one head-gimbal assembly (HGA) 510 including a magnetic-recording head 510a, a lead-suspension 510c attached to the magnetic-recording head 510a, and a load beam 510d attached to a slider 510b, which includes the magnetic-recording head 510a at a distal end of the slider 510b; the slider 510b is attached at the distal end of the load beam 510d to a gimbal portion of the load beam 510d. HDD 501 also includes at least one magnetic-recording disk 520 rotatably mounted on a spindle 526 and a drive motor (not shown) mounted in a disk-enclosure base 101-1 and attached to the spindle 526 for rotating the magnetic-recording disk 520. The magnetic-recording head 510a that includes a write element, a so-called writer, and a read element, a so-called reader, is disposed for respectively writing and reading information, referred to by the term of art, “data,” stored on the magnetic-recording disk 520 of HDD 501. The magnetic-recording disk 520, or a plurality (not shown) of magnetic-recording disks, may be affixed to the spindle 526 with a disk clamp 522. The disk clamp 522 includes a circular plate; and, the circular plate includes a plurality of fastener holes, of which fastener hole 530 is an example. The plurality of fastener holes, of which fastener hole 530 is an example, is configured to accept a plurality of fasteners, of which fastener 532 (indicated by the hex-shaped “star” representative of a Torx™ screw) is an example, such that the fasteners are configured to fasten the disk clamp 522 to couple the magnetic-recording disk 520 with the spindle 526. HDD 501 further includes an arm 534 attached to HGA 510, a carriage 536, a voice-coil motor (VCM) that includes an armature 538 including a voice coil 540 attached to the carriage 536; and a stator 544 including a voice-coil magnet (not shown); the armature 538 of the VCM is attached to the carriage 536 and is configured to move the arm 534 and HGA 510 to access portions of the magnetic-recording disk 520, as the carriage 536 is mounted on a pivot-shaft 548 with an interposed pivot-bearing assembly 552. HDD 501 also includes a load-unload ramp 590 for HGA 510 that is configured to engage a tongue 510e of HGA 510 at the far distal end of HGA 510 when arm 534 is retracted from a position for flying the magnetic-recording head 510a in proximity with the magnetic-recording disk 520.

With further reference to FIG. 5, in accordance with one or more embodiments of the present invention, electrical signals, for example, current to the voice coil 540 of the VCM, write signals to and read signals from the magnetic-recording head 510a, are provided by a flexible cable 556. Interconnection between the flexible cable 556 and the magnetic-recording head 510a may be provided by an arm-electronics (AE) module 560, which may have an on-board pre-amplifier for the read signal, as well as other read-channel and write-channel electronic components. The flexible cable 556 is coupled to an electrical-connector block 564, which provides electrical communication through electrical feedthroughs (not shown) provided by the disk-enclosure base 101-1. The disk-enclosure base 101-1, also referred to as a casting, depending upon whether the disk-enclosure base 101-1 is cast, in conjunction with a disk-enclosure cover 101-2 (not shown, here; but, see FIG. 1) provides a sealed, protective disk enclosure 101 for the information storage components of HDD 501.

With further reference to FIG. 5, in accordance with one or more embodiments of the present invention, other electronic components (not shown), including a disk controller and servo electronics including a digital-signal processor (DSP), provide electrical signals to the drive motor, the voice coil 540 of the VCM and the magnetic-recording head 510a of HGA 510. The electrical signal provided to the drive motor enables the drive motor to spin providing a torque to the spindle 526 which is in turn transmitted to the magnetic-recording disk 520 that is affixed to the spindle 526 by the disk clamp 522; as a result, the magnetic-recording disk 520 spins in a direction 572. The spinning magnetic-recording disk 520 creates an airflow including an air-stream, and a cushion of air that acts as an air bearing on which the air-bearing surface (ABS) of the slider 510b rides so that the slider 510b flies in proximity with the surface of the magnetic-recording disk 520 with minimal contact between the slider 510b and the magnetic-recording disk 520 in which information is recorded. The electrical signal provided to the voice coil 540 of the VCM enables the magnetic-recording head 510a of HGA 510 to access a track 576 on which information is recorded. Thus, the armature 538 of the VCM swings through an arc 580 which enables HGA 510 attached to the armature 538 by the arm 534 to access various tracks on the magnetic-recording disk 520. Information is stored on the magnetic-recording disk 520 in a plurality of concentric tracks (not shown) arranged in sectors on the magnetic-recording disk 520, for example, sector 584. Correspondingly, each track is composed of a plurality of sectored track portions, for example, sectored track portion 588. Each sectored track portion 588 is composed of recorded data and a header containing a servo-burst-signal pattern, for example, an ABCD-servo-burst-signal pattern, information that identifies a track 576, and error correction code information. In accessing the track 576, the read element of the magnetic-recording head 510a of HGA 510 reads the servo-burst-signal pattern which provides a position-error-signal (PES) to the servo electronics, which controls the electrical signal provided to the voice coil 540 of the VCM, enabling the magnetic-recording head 510a to follow the track 576. Upon finding the track 576 and identifying a particular sectored track portion 588, the magnetic-recording head 510a either reads data from the track 576, or writes data to, the track 576 depending on instructions received by the disk controller from an external agent, for example, a microprocessor of a computer system.

With further reference to FIGS. 1-5, embodiments of the present invention encompass within their scope HDD 501 that includes a disk enclosure 101 configured to shield HDD 501 against EMI, a spindle motor (not shown) mounted in the disk-enclosure base 101-1 of the disk enclosure 101, a spindle 526 coupled to the spindle motor, at least one magnetic-recording disk 520 rotatably mounted on the spindle 526, and at least one magnetic-recording head 510a disposed to read data from, and to write data to, the magnetic-recording disk 520. The disk enclosure 101 is configured to shield an interior space enclosed by the disk enclosure 101 against EMI. The vertical flange 101-3b of the disk-enclosure cover 101-3 may be ohmically coupled with low impedance to a top portion 101-1b1 of the side 101-1b of the disk-enclosure base 101, as described above, particularly, in the discussion of FIG. 4. Moreover, to facilitate the ohmic contact, an e-coat layer is removed from the disk-enclosure base 101-1 at top portions of the sides 101-1b through 101-1e of the disk-enclosure base 101-1. For example, top portion 101-1b1 of the side 101-1b makes ohmic contact with the vertical flange 101-3b of the supplementary disk-enclosure cover 101-3 through a contacting portion 101-3b4, where the e-coat layer has been removed from a top portion 101-1b1 of the side 101-1b of the disk-enclosure base 101. Thus, in accordance with embodiments of the present invention, the disk enclosure 101 is configured to reduce SER during reads by the magnetic-recording head 510a of data from the magnetic-recording disk 522. To achieve low SER, in accordance with embodiments of the present invention, the supplementary disk-enclosure cover 101-3 shields an interior space enclosed by the disk-enclosure base 101-1 and the disk-enclosure cover 101-2 against electromagnetic interference with a frequency of between about 200 MHz to about 2 GHz by reducing an electric field component of an electromagnetic field associated with EMI within the interior space to less than about 7 volts/meter (V/m). In one embodiment of the present invention, EMI includes radio frequency interference (RFI), without limitation thereto.

The foregoing descriptions of specific embodiments of the present invention have been presented for purposes of illustration and description. They are not intended to be exhaustive or to limit the invention to the precise forms disclosed, and many modifications and variations are possible in light of the above teaching. The embodiments described herein were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A supplementary disk-enclosure cover configured to shield a hard-disk drive against electromagnetic interference, said supplementary disk-enclosure cover comprising:
a top having an outer perimeter and an inner perimeter, said outer perimeter about parallel to said inner perimeter, said top disposed between said outer perimeter and said inner perimeter and having a flattened annular shape; and
vertical flanges attached to and extending down from said outer perimeter of said top at about right angles to said top;
wherein said vertical flanges are configured to cover respective gaps between a disk-enclosure cover and a disk-enclosure base to which said disk-enclosure cover is attached.

2. The supplementary disk-enclosure cover of claim 1, wherein said outer perimeter has about a rectangular shape.

3. The supplementary disk-enclosure cover of claim 2, wherein a width and a length of said top at said inner perimeter are less than a width and a length of said disk-enclosure base.

4. The supplementary disk-enclosure cover of claim 1, wherein said top includes a plurality of supplementary holes configured to accept fasteners to fasten said top to said disk-enclosure base.

5. The supplementary disk-enclosure cover of claim 4, wherein said plurality of supplementary holes is configured to align with a plurality of holes in said disk-enclosure base.

6. The supplementary disk-enclosure cover of claim 1, wherein said top is configured to clamp said disk-enclosure cover to said disk-enclosure base.

7. The supplementary disk-enclosure cover of claim 1, wherein said vertical flanges are configured to make electrical contact with said disk-enclosure base.

8. The supplementary disk-enclosure cover of claim 1, said supplementary disk-enclosure cover further comprising stainless steel.

9. The supplementary disk-enclosure cover of claim 1, wherein said vertical flange includes an inward projecting portion configured to press against a side of said disk-enclosure base.

10. The supplementary disk-enclosure cover of claim 9, wherein said vertical flange includes a skirt extending below said inward projecting portion configured to be disposed about parallel to said side of said disk-enclosure base.

11. The supplementary disk-enclosure cover of claim 1, said supplementary disk-enclosure cover further comprising spring steel.

12. A disk enclosure configured to shield a hard-disk drive against electromagnetic interference, said disk enclosure comprising:
a disk-enclosure base, comprising:
a bottom; and
sides attached to said bottom in a boxlike configuration;
a disk-enclosure cover; and
a supplementary disk-enclosure cover comprising:
a top having an outer perimeter and an inner perimeter, said outer perimeter about parallel to said inner perimeter, said top disposed between said outer perimeter and said inner perimeter and having a flattened annular shape; and
vertical flanges attached to and extending down from said outer perimeter of said top at about right angles to said top;
wherein said vertical flanges are configured to cover respective gaps between a disk-enclosure cover and a disk-enclosure base to which said disk-enclosure cover is attached.

13. The disk enclosure of claim 12, wherein an e-coat layer is removed from said disk-enclosure base at a top portion of said side of said disk-enclosure base.

14. The disk enclosure of claim 13, wherein said vertical flange includes an inward projecting portion that presses against said top portion of said side of said disk-enclosure base.

15. The disk enclosure of claim 13, wherein said supplementary disk-enclosure cover is ohmically coupled with low impedance by said vertical flange through said top portion of said side to said disk-enclosure base.

16. The disk enclosure of claim 12, wherein said disk-enclosure further comprises:
a plurality of fasteners, said fasteners fastening said top to said disk-enclosure base.

17. The disk enclosure of claim 16, wherein said fasteners are screws.

18. The disk enclosure of claim 12, wherein said top is configured to clamp said disk-enclosure cover to said disk-enclosure base.

19. The disk enclosure of claim 12, wherein said supplementary disk-enclosure cover shields an interior space enclosed by said disk-enclosure base and said disk-enclosure cover against electromagnetic interference with a frequency of between about 200 MHz to about 2 GHz by reducing an electric field component of an electromagnetic field associated with said electromagnetic interference within said interior space to less than about 7 volts/meter (V/m).

20. A hard-disk drive shielded against electromagnetic interference, comprising:
a disk enclosure comprising:
a disk-enclosure base, comprising:
a bottom; and
sides of said disk-enclosure base attached to said bottom in a boxlike configuration;
a disk-enclosure cover; and
a supplementary disk-enclosure cover comprising:
a top having an outer perimeter and an inner perimeter, said outer perimeter about parallel to said inner perimeter, said top disposed between said outer perimeter and said inner perimeter and having a flattened annular shape; and
vertical flanges attached to and extending down from said outer perimeter of said top at about right angles to said top;
wherein said vertical flanges are configured to cover respective gaps between a disk-enclosure cover and a disk-enclosure base to which said disk-enclosure cover is attached;
a spindle motor mounted in said disk-enclosure base;
a spindle coupled to said spindle motor;
at least one magnetic-recording disk rotatably mounted on said spindle; and
at least one magnetic-recording head disposed to read data from, and to write data to, said magnetic-recording disk;
wherein said disk enclosure is configured to shield an interior space enclosed by said disk enclosure against electromagnetic interference.

21. The hard-disk drive of claim 20, wherein said disk enclosure is configured to reduce soft error rate during reads by said magnetic-recording head of data from said magnetic-recording disk.

22. The hard-disk drive of claim 20, wherein an e-coat layer is removed from said disk-enclosure base at a top portion of said side of said disk-enclosure base.

23. The hard-disk drive of claim 22, wherein said supplementary disk-enclosure cover is ohmically coupled with low impedance by said vertical flange through said top portion of said side to said disk-enclosure base.

24. The hard-disk drive of claim 20, wherein said supplementary disk-enclosure cover shields an interior space enclosed by said disk-enclosure base and said disk-enclosure cover against electromagnetic interference with a frequency of between about 200 MHz to about 2 GHz by reducing an electric field component of an electromagnetic field associated with said electromagnetic interference within said interior space to less than about 7 volts/meter (V/m).

25. The hard-disk drive of claim 24, wherein said electromagnetic interference comprises radio frequency interference.
